(19) United States
(12) Patent Application Publication
(10) Pub. No.: US 2026/0271351 A1
(43) Pub. Date: Sep. 10, 2026

(54) SEMICONDUCTOR DEVICE

(71) Applicants: Kabushiki Kaisha Toshiba, Kawasaki (JP); Toshiba Electronic Devices & Storage Corporation, Kawasaki (JP)

(72) Inventor: Tsuyoshi KACHI, Kanazawa Ishikawa (JP)

(21) Appl. No.: 19/300,192

(22) Filed: Aug. 14, 2025

(30) Foreign Application Priority Data
Mar. 7, 2025 (JP) 2025-036616

(51) Int. Cl. H10D 62/10; H10D 30/65; H10D 62/17

(52) U.S. Cl. CPC H10D 62/111; H10D 30/65; H10D 62/364

(57) ABSTRACT

According to one embodiment, a semiconductor device includes first and second electrodes, first to third semiconductor regions, a gate electrode, and first and second conductive portions. The first semiconductor region includes first and second parts. The second part is provided around the first part along a first plane. The first conductive portion is provided in the first part via a first insulating layer. An upper part of the first conductive portion faces the second semiconductor region via the first insulating layer. The second conductive portion is provided in the second part via a second insulating layer. An upper end of the second conductive portion is positioned lower than a lower end of the second semiconductor region. The second electrode is electrically connected to the second semiconductor region, the third semiconductor region, and the first conductive portion. The second electrode is electrically isolated from the second conductive portion.

### CROSS-REFERENCE TO RELATED APPLICATIONS

This application is based upon and claims the benefit of priority from Japanese Patent Application No. 2025-036616, filed on Mar. 7, 2025; the entire contents of which are incorporated herein by reference.

### FIELD

Embodiments described herein relate generally to a semiconductor device.

### BACKGROUND

Semiconductor devices such as Metal Oxide Semiconductor Field Effect Transistors (MOSFETs) are used, for example, in power conversion applications. It is desirable that the withstand voltage of semiconductor devices be high.

### BRIEF DESCRIPTION OF THE DRAWINGS

FIG. 1 is a plan view illustrating the semiconductor device according to an embodiment;

FIG. 2 is an enlarged plan view of part II of FIG. 1;

FIG. 3 is the III-III cross-sectional view of FIG. 2;

FIG. 4 is the IV-IV cross-sectional view of FIG. 2;

FIG. 5 is the V-V cross-sectional view of FIG. 2;

FIGS. 6A and 6B are cross-sectional views illustrating a method for manufacturing the semiconductor device according to the embodiment;

FIGS. 7A and 7B are cross-sectional views illustrating the method for manufacturing the semiconductor device according to the embodiment;

FIGS. 8A and 8B are cross-sectional views illustrating the method for manufacturing the semiconductor device according to the embodiment;

FIG. 9 is a cross-sectional view illustrating a part of a semiconductor device according to a reference example;

FIG. 10 is a plan view illustrating a part of the semiconductor device according to a first modification;

FIG. 11 is the XI-XI cross-sectional view of FIG. 10;

FIG. 12 is a cross-sectional view illustrating a part of the semiconductor device according to a second modification;

FIG. 13 is a cross-sectional view illustrating a part of a semiconductor device according to a third modification;

FIG. 14 is a plan view illustrating a part of the semiconductor device according to a fourth modification; and

FIG. 15 is the XV-XV cross-sectional view of FIG. 14.

### DETAILED DESCRIPTION

According to one embodiment, a semiconductor device includes a first electrode, a first semiconductor region of a first conductivity type, a second semiconductor region of a second conductivity type, a third semiconductor region of the first conductivity type, a gate electrode, a first conductive portion, a second conductive portion, and a second electrode. The first semiconductor region is provided on the first electrode. The first semiconductor region includes a first part and a second part. The second part is provided around the first part along a first plane. The first plane is perpendicular to a first direction from the first electrode toward the first part. The second semiconductor region is provided on the first part and the second part. The third semiconductor region is provided on the second semiconductor region and positioned on the first part. The gate electrode faces the second semiconductor region via a gate insulating layer. The first conductive portion is provided in the first part via a first insulating layer. An upper part of the first conductive portion faces the second semiconductor region via the first insulating layer. The second conductive portion is provided in the second part via a second insulating layer. An upper end of the second conductive portion is positioned lower than a lower end of the second semiconductor region. The second electrode is provided on the second semiconductor region, the third semiconductor region, and the first conductive portion. The second electrode is electrically connected to the second semiconductor region, the third semiconductor region, and the first conductive portion. The second electrode is electrically isolated from the second conductive portion.

Embodiments of the invention will now be described with reference to the drawings. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated. In the drawings and the specification of the application, components similar to those described therein above are marked with like reference numerals, and a detailed description is omitted as appropriate.

In the following descriptions and drawings, the notations n⁺, n⁻ and p⁺, p, p⁻ represent relative levels of impurity concentrations in conductivity types. That is, the notation with “+” shows a relatively higher impurity concentration than an impurity concentration for the notation without any of “+” and “−”. The notation with “−” shows a relatively lower impurity concentration than the impurity concentration for the notation without any of them. These notations represent relative levels of net impurity concentrations after the mutual compensation of these impurities when respective regions include both of a p-type impurity and an n-type impurity.

The embodiments described below may be implemented by reversing the p-type and the n-type of the semiconductor regions.

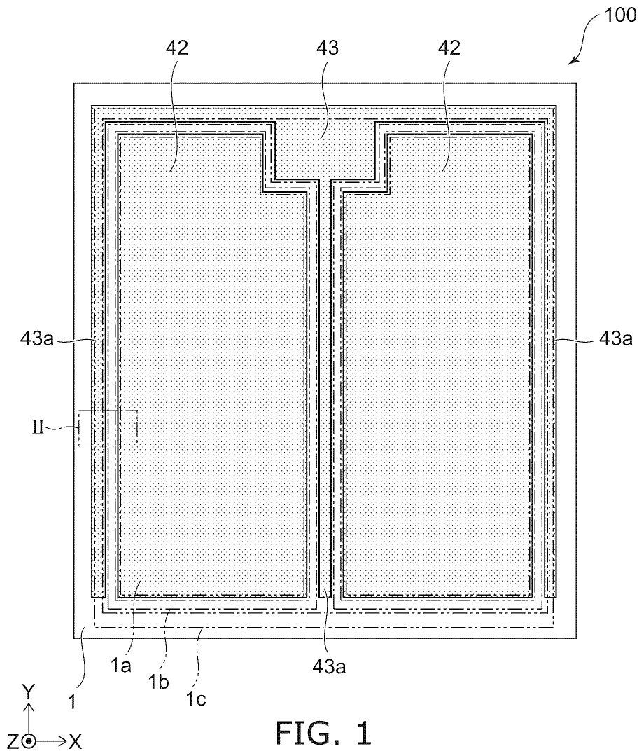

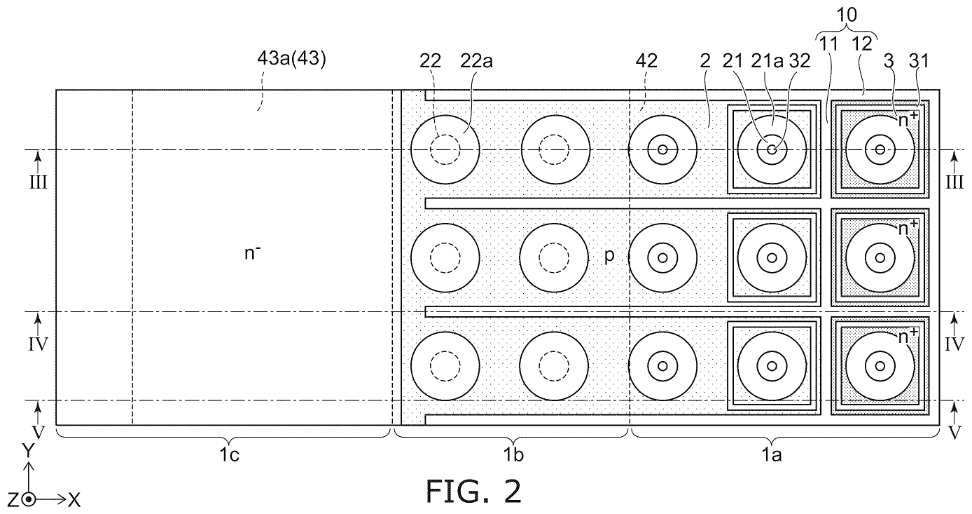

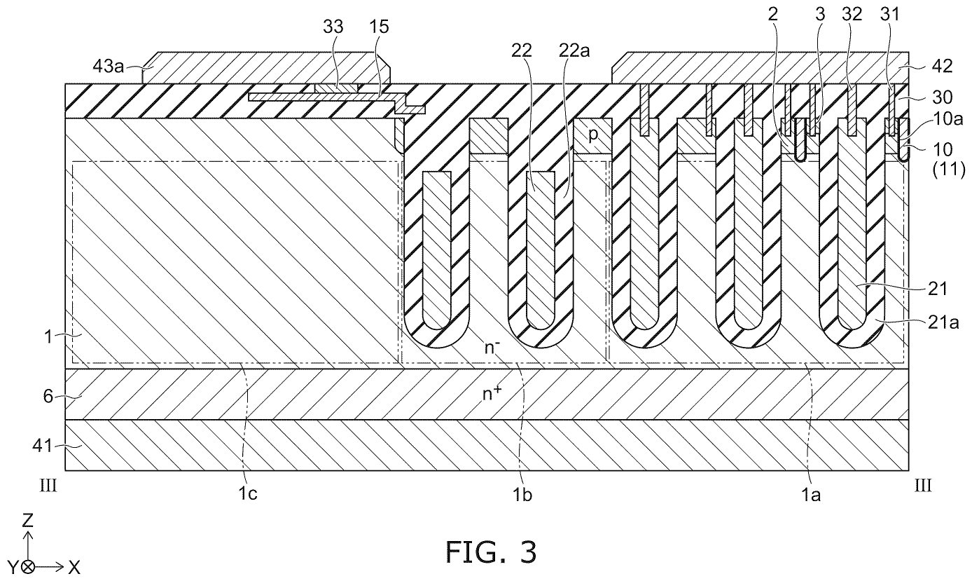

FIG. 1 is a plan view illustrating the semiconductor device according to an embodiment. FIG. 2 is an enlarged plan view of part II of FIG. 1. FIGS. 3 to 5 are, respectively, the III-III cross-sectional view, the IV-IV cross-sectional view, and the V-V cross-sectional view of FIG. 2.

The semiconductor device 100 according to the embodiment is a MOSFET. As shown in FIGS. 1 to 5, the semiconductor device 100 includes an n⁻-type drift region 1 (a first semiconductor region), a p-type base region 2 (a second semiconductor region), an n⁺-type source region 3 (a third semiconductor region), an n⁺-type drain region 6 (a sixth semiconductor region), a gate electrode 10, a conductive layer 15, a first conductive portion 21, a second conductive portion 22, an insulating layer 30, a contact plug 31, a contact plug 32, a contact plug 33, a drain electrode 41 (a first electrode), a source electrode 42 (a second electrode), and a gate pad 43 (a third electrode). The n-type is an example of a first conductivity type. The p-type is an example of a second conductivity type. In FIG. 2, the conductive layer 15, the insulating layer 30, and the contact plug 33 are omitted, and the source electrode 42 and the gate pad 43 are indicated by dashed lines.

An XYZ orthogonal coordinate system is used in the description of the embodiments. A direction from the drain electrode 41 toward the n⁻-type drift region 1 is taken as a Z-direction (a first direction). One direction perpendicular to the Z-direction is taken as an X-direction (a second direction). The direction perpendicular to the Z-direction and crossing the X-direction is taken as a Y-direction (a third direction). The Y-direction may be perpendicular to the X-direction or need not be. In the description, the direction from the drain electrode 41 toward the n⁻-type drift region 1 is referred to as “up/above/higher than”, and the opposite direction is referred to as “down/below/lower than”. These directions are based on the relative positional relationship between the drain electrode 41 and the n⁻-type drift region 1, and are independent of the direction of gravity.

As shown in FIG. 1, the source electrode 42 and the gate pad 43 are provided on the upper surface of the semiconductor device 100. The source electrode 42 and the gate pad 43 are separated from each other and electrically isolated. In the illustrated example, multiple source electrodes 42 are provided in the X-direction. The gate pad 43 includes a gate wiring 43a that is provided around the source electrode 42 along the X-Y plane (a first plane).

As shown in FIG. 2, the p-type base region 2, the n⁺-type source region 3, the gate electrode 10, the first conductive portion 21, the contact plug 31, the contact plug 32, and the like are provided under the source electrode 42.

As shown in FIGS. 3 to 5, the drain electrode 41 is provided on the lower surface of the semiconductor device 100. The n⁺-type drain region 6 is provided on the drain electrode 41 and is electrically connected to the drain electrode 41. The n-type drift region 1 is provided on the n⁺-type drain region 6 and is electrically connected to the drain electrode 41 via the n⁺-type drain region 6. The n-type impurity concentration in the n⁻-type drift region 1 is less than the n-type impurity concentration in the n⁺-type drain region 6.

As shown in FIGS. 1 to 5, the n⁻-type drift region 1 includes a first part 1a, a second part 1b, and a third part 1c. In FIGS. 1 to 5, the first part 1a, the second part 1b, and the third part 1c are indicated by two-dot chain lines.

The first part 1a includes the central portion of the n⁻-type drift region 1 in the X-Y plane. The second part 1b is provided around the first part 1a along the X-Y plane. The third part 1c is provided around the second part 1b along the X-Y plane.

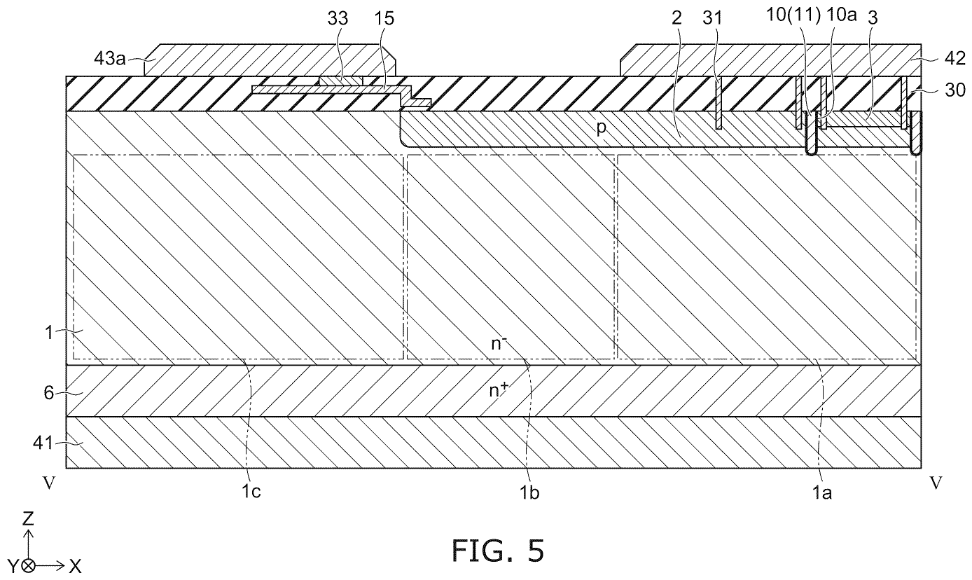

As shown in FIGS. 3 and 5, the p-type base region 2 is provided on the first part 1a and the second part 1b. The n⁺-type source region 3 is provided on the p-type base region 2 and is positioned on the first part 1a.

As shown in FIGS. 2 and 3, the gate electrode 10 faces the p-type base region 2 via the gate insulating layer 10a. Preferably, the gate electrode 10 faces a part of the n⁻-type drift region 1, the p-type base region 2, and at least a part of the n⁺-type source region 3 via the gate insulating layer 10a.

The first conductive portion 21 is provided in the first part 1a via a first insulating layer 21a. The upper part of the first conductive portion 21 faces the p-type base region 2 via the first insulating layer 21a.

The second conductive portion 22 is provided in the second part 1b via a second insulating layer 22a. In FIG. 2, the second conductive portion 22 is indicated by dashed lines. The upper end of the second conductive portion 22 is positioned lower than the lower end of the p-type base region 2. For example, the upper end of the second conductive portion 22 is positioned lower than the p-n junction between the n⁻-type drift region 1 and the p-type base region 2. In the cross-sectional view shown in FIG. 3, the second conductive portion 22 is arranged with the first conductive portion 21 in the X-direction.

As shown in FIGS. 3 to 5, the insulating layer 30 is provided on the n⁻-type drift region 1, the p-type base region 2, the n⁺-type source region 3, the gate electrode 10, the first conductive portion 21, and the second conductive portion 22. The contact plug 31 and the contact plug 32 extend along the Z-direction in the insulating layer 30.

The source electrode 42 is provided on the insulating layer 30, the contact plug 31, and the contact plug 32, and is positioned on the first part 1a. The contact plug 31 is positioned between the p-type base region 2 and the source electrode 42 and electrically connects the p-type base region 2 and the n⁺-type source region 3 to the source electrode 42. The contact plug 32 is positioned between the first conductive portion 21 and the source electrode 42 and electrically connects the first conductive portion 21 to the source electrode 42.

The second conductive portion 22 is electrically isolated from the source electrode 42. For example, the electric potential of the second conductive portion 22 is floating.

On the third part 1c, the conductive layer 15 is provided in the insulating layer 30. The conductive layer 15 is electrically connected to the gate electrode 10. The gate pad 43 and the gate wiring 43a are positioned on the third part 1c. The contact plug 33 is provided between the conductive layer 15 and the gate wiring 43a, and electrically connects the conductive layer 15 and the gate wiring 43a.

As shown in FIG. 2, multiple first conductive portions 21 are provided in the X-direction and the Y-direction. Multiple second conductive portions 22 are provided in a direction perpendicular to the direction from the first part 1a to the second part 1b. In the illustrated example, multiple second conductive portions 22 are also provided in the direction from the first part 1a to the second part 1b.

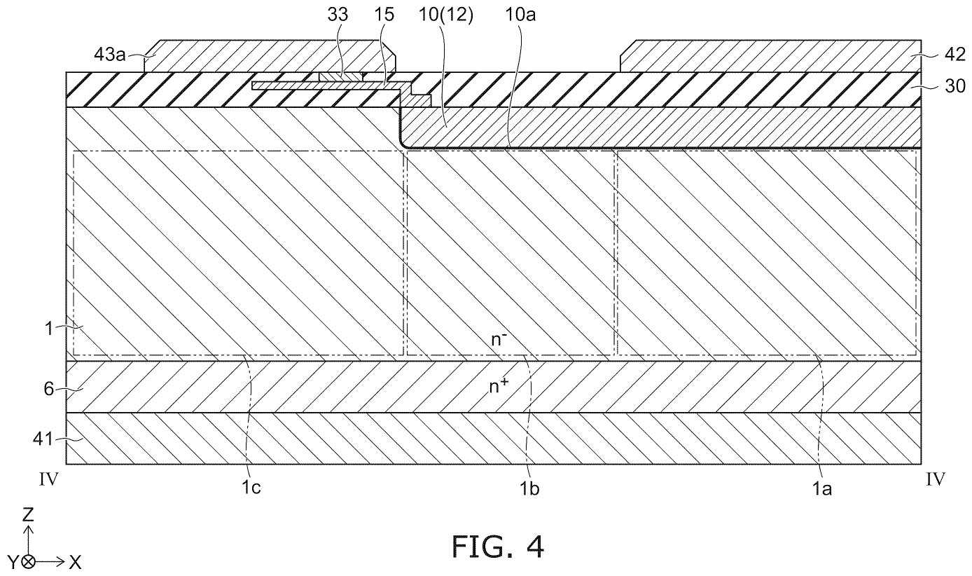

The gate electrode 10 includes a first electrode part 11 and a second electrode part 12. The first electrode part 11 extends in the Y-direction between first conductive portions 21 that are adjacent in the X-direction. The second electrode part 12 extends in the X-direction between first conductive portions 21 that are adjacent in the Y-direction and between second conductive portions 22 that are adjacent in the Y-direction. As shown in FIG. 4, the end portion in the X-direction of the second electrode part 12 is connected to the conductive layer 15.

An example of the materials of each component will now be described. The n⁻-type drift region 1, the p-type base region 2, the n⁺-type source region 3, and the n⁺-type drain region 6 include silicon, silicon carbide, gallium nitride, or gallium arsenide, as a semiconductor material. When silicon is used as the semiconductor material, arsenic, phosphorus, or antimony can be used as the n-type impurity. Boron can be used as the p-type impurity. The gate electrode 10, the conductive layer 15, the first conductive portion 21, and the second conductive portion 22 include polysilicon to which impurities have been doped. The gate insulating layer 10a, the first insulating layer 21a, the second insulating layer 22a, and the insulating layer 30 include an insulating material such as silicon oxide, silicon nitride, or silicon oxynitride. The contact plugs 31 to 33, the drain electrode 41, the source electrode 42, and the gate pad 43 include a metal material. For example, the contact plugs 31 to 33 include a laminated structure of titanium, titanium nitride, and tungsten. The drain electrode 41, the source electrode 42, and the gate pad 43 include aluminum or copper.

The operation of the semiconductor device 100 will now be described. When a voltage not less than the threshold is applied to the gate electrode 10, a channel (an inversion layer) is formed in the p-type base region 2. When a channel is formed under the condition that the electric potential of the drain electrode 41 is higher than the electric potential of the source electrode 42, electrons flow from the source electrode 42 to the drain electrode 41 through the channel. As a result, the semiconductor device 100 is turned on. When the voltage applied to the gate electrode 10 falls below the threshold, the channel in the p-type base region 2 disappears, and the semiconductor device 100 is turned off.

In the semiconductor device 100, the n⁺-type source region 3 is provided on the first part 1a. When the semiconductor device 100 is in the on-state, current mainly flows through the first part 1a. The region including the first part 1a, the p-type base region 2, and the n⁺-type source region 3 functions as a cell region for conducting current. The region including the second part 1b and the third part 1c functions as a termination region for the depletion layer to spread when the semiconductor device 100 is turned off.

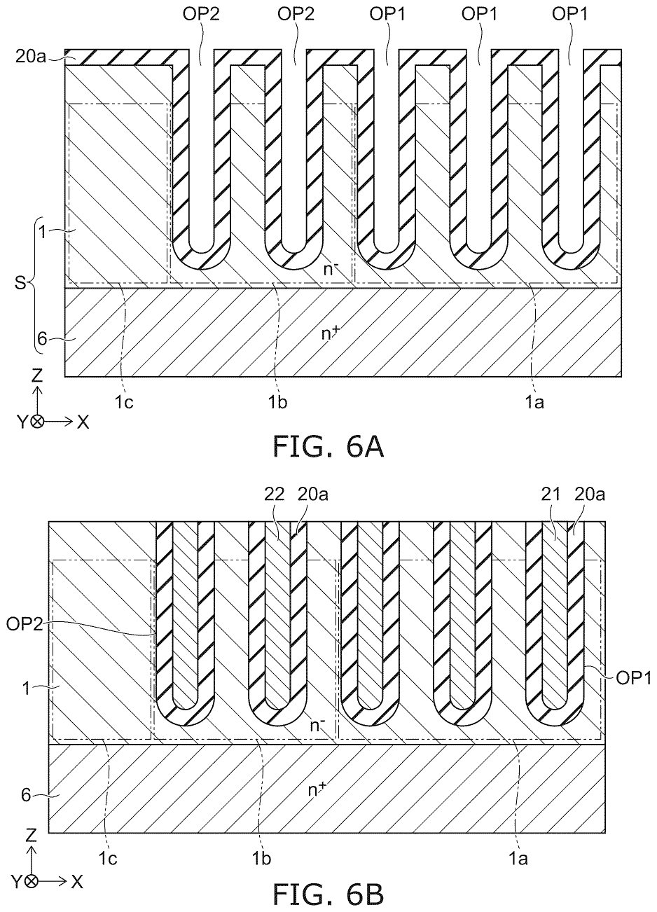

FIGS. 6A, 6B, 7A, 7B, 8A, and 8B are cross-sectional views illustrating a method for manufacturing the semiconductor device according to the embodiment.

First, a semiconductor substrate S including the n⁻-type drift region 1 and the n⁺-type drain region 6 is prepared. The n⁻-type drift region 1 includes the first part 1a, the second part 1b, and the third part 1c. Multiple openings OP1 are formed in the first part 1a, and multiple openings OP2 are formed in the second part 1b by photolithography and reactive ion etching (RIE). The multiple openings OP1 and the multiple openings OP2 are arranged in the X-direction and the Y-direction. By thermal oxidation or chemical vapor deposition (CVD), as shown in FIG. 6A, an insulating layer 20a is formed along the upper surface of the n⁻-type drift region 1, the inner surface of each opening OP1, and the inner surface of each opening OP2.

A conductive layer that fills each opening OP1 and each opening OP2 is formed on the insulating layer 20a by CVD. The upper surface of the conductive layer and the upper surface of the insulating layer 20a are polished. As a result, as shown in FIG. 6B, the first conductive portion 21 is formed inside each opening OP1, and the second conductive portion 22 is formed inside each opening OP2.

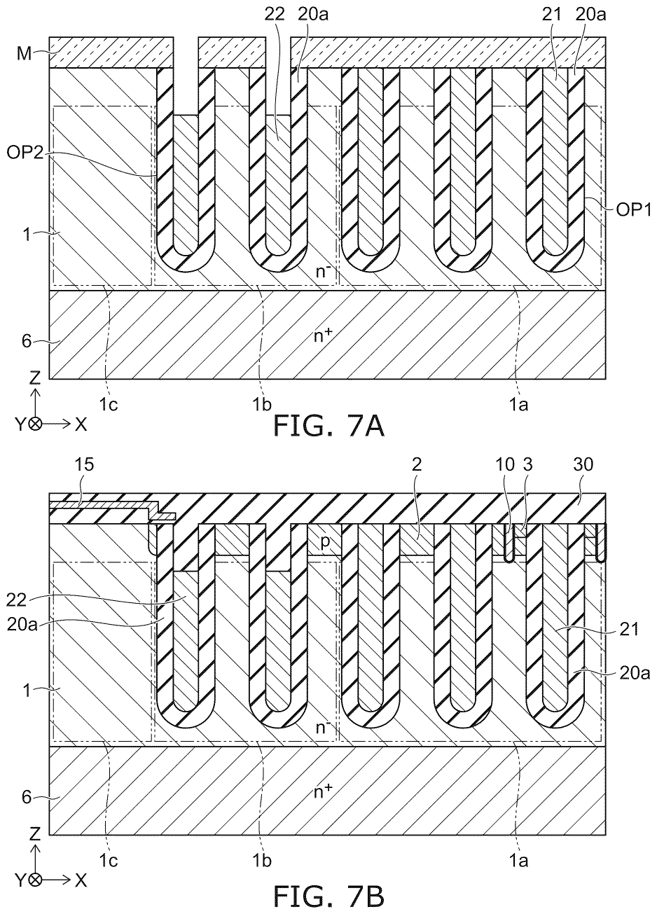

A mask M covering regions other than the opening OP2 is formed by photolithography and RIE. The mask M may be a photoresist. A part of the second conductive portion 22 is removed by RIE. As a result, as shown in FIG. 7A, the position of the upper end of the second conductive portion 22 becomes lower than the position of the upper end of the first conductive portion 21.

Subsequently, the gate electrode 10 and the p-type base region 2 are sequentially formed on the upper surfaces of the first part 1a and the second part 1b. Above the first part 1a, the n⁺-type source region 3 is formed on the p-type base region 2. As shown in FIG. 7B, the insulating layer 30 covering the p-type base region 2, the n⁺-type source region 3, and the gate electrode 10 is formed. At this time, a conductive layer 15 connected to the gate electrode 10 is formed in the insulating layer 30.

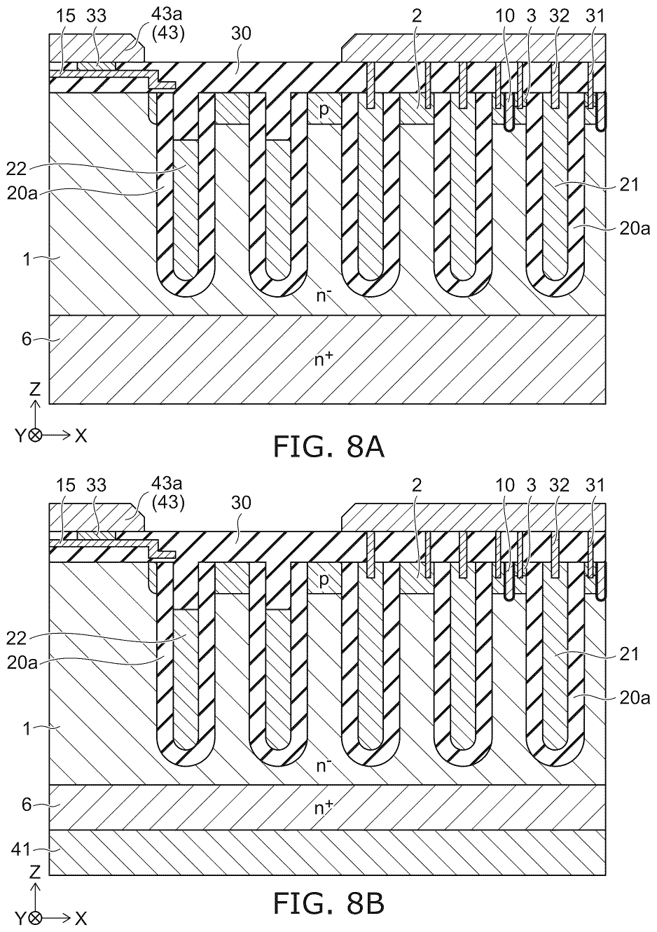

Multiple openings are formed in the insulating layer 30 by photolithography and RIE. The contact plugs 31 to 33 are respectively formed in the multiple openings by CVD. A metal layer is formed on the insulating layer 30 and the contact plugs 31 to 33 by sputtering. As shown in FIG. 8A, this metal layer is patterned to form the source electrode 42 and the gate pad 43.

The lower surface of the n⁺-type drain region 6 is ground until the n⁺-type drain region 6 reaches a predetermined thickness. As shown in FIG. 8B, the drain electrode 41 is formed on the ground lower surface by sputtering. Through the above steps, the semiconductor device 100 according to the embodiment is manufactured.

In the manufacturing method of the semiconductor device 100, as shown in FIG. 6A, multiple openings OP2 are formed around multiple openings OP1. If multiple openings OP2 are not formed and only multiple openings OP1 are formed, a difference arises between the condition of the surroundings of an opening OP1 located at the outer periphery of the first part 1a and the condition of the surroundings of an opening OP1 located at the center of the first part 1a. For example, an opening OP1 located at the center is adjacent to two openings OP1 in the X-direction and the Y-direction. An opening OP1 located at the outermost periphery is adjacent to only one opening OP1 in the X-direction or the Y-direction. In such a case, the variation between the shape of the opening OP1 located at the center of the first part 1a and the shape of the opening OP1 located at the outer periphery of the first part 1a increases. The variation in the shape is, for example, caused by differences in the processing accuracy of photolithography and the concentration of etching gases in RIE that occur between regions with a high density of openings OP1 and regions with a low density of openings OP1. The variation in the shape of the opening OP1 causes variations in the thickness of the first insulating layer 21a, variations in the depth of the first conductive portion 21, or variations in the depth of the first insulating layer 21a, and the like. As a result, the withstand voltage of the semiconductor device 100 may decrease.

When multiple openings OP2 are formed around the multiple openings OP1, the condition of the surroundings of an opening OP1 located at the outer periphery of the first part 1a and the condition of the surroundings of an opening OP1 located at the center of the first part 1a become substantially the same. For example, an opening OP1 located at the outermost periphery is adjacent to one opening OP1 and one opening OP2 in the X-direction or the Y-direction. As a result, the variation in the shape of the opening OP1 can be reduced. Consequently, the reduction in the withstand voltage of the semiconductor device 100 due to the variation in the shape of the opening OP1 can be suppressed. The second conductive portion 22, which is formed in the opening OP2, is electrically isolated from the source electrode 42. Therefore, the variation in the shape of the opening OP2 does not directly affect the withstand voltage of the semiconductor device 100.

Additionally, it is preferable for the p-type base region 2 to be provided not only on the first part 1a but also on the second part 1b. It is not easy to selectively and accurately form the p-type base region 2 only on the first part 1a. By also forming the p-type base region 2 on the second part 1b, the p-type base region 2 can be formed more reliably throughout the entirety of the region above the first part 1a. As a result, the characteristics of the semiconductor device 100 can be further stabilized.

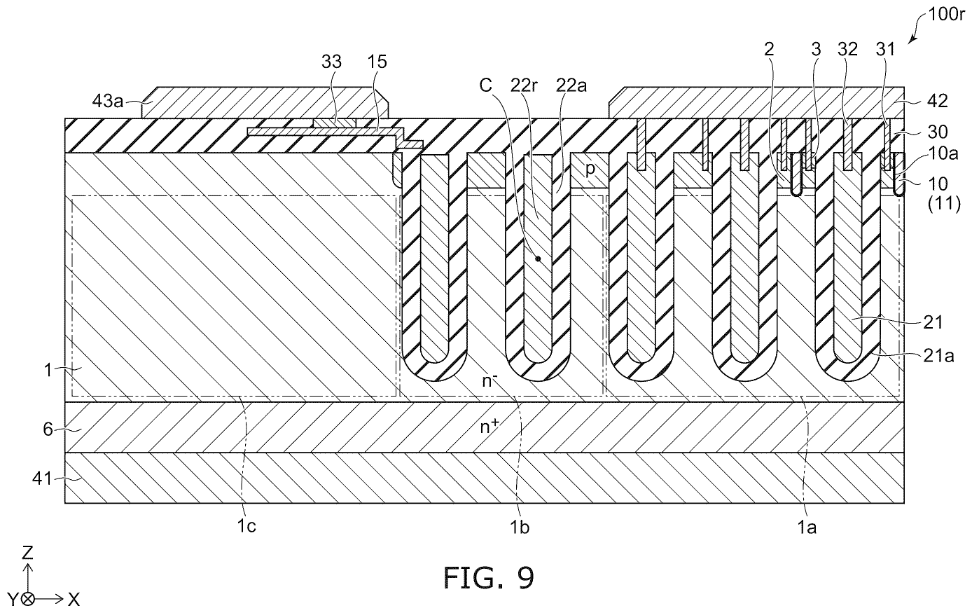

FIG. 9 is a cross-sectional view illustrating a part of a semiconductor device according to a reference example.

The semiconductor device 100r shown in FIG. 9, compared to the semiconductor device 100 shown in FIG. 3, includes the second conductive portion 22r in place of the second conductive portion 22. The upper end of the second conductive portion 22r is positioned higher than the lower end of the p-type base region 2. In the X-direction or Y-direction, the upper part of the second conductive portion 22r faces the p-type base region 2 via the second insulating layer 22a.

When the semiconductor device 100r is in the off-state, a voltage Vds is applied between the drain electrode 41 and the source electrode 42. At this time, the electric potential of the n⁺-type drain region 6 is substantially the same as the electric potential of the drain electrode 41. The electric potentials of the p-type base region 2 and the first conductive portion 21 are substantially the same as the electric potential of the source electrode 42. Between the n⁺-type drain region 6 and the p-type base region 2, a potential gradient corresponding to the voltage Vds is generated in the n⁻-type drift region 1.

The second conductive portion 22r is electrically isolated from the source electrode 42. The electric potential of the second conductive portion 22r is generally the same as that of the n⁻-type drift region 1 adjacent to the center C in the Z-direction of the second conductive portion 22r. At this time, the potential difference between the center C of the second conductive portion 22r and the adjacent n⁻-type drift region 1 is small. However, a large potential difference arises between the upper part of the second conductive portion 22r and the p-type base region 2. Due to this potential difference, breakdown may occur near the interface between the upper part of the second insulating layer 22a and the p-type base region 2. In particular, the p-type impurity concentration in the p-type base region 2 is greater than the n-type impurity concentration in the n⁻-type drift region 1. In the p-type base region 2, compared with the n⁻-type drift region 1, the depletion layer is less likely to expand. Therefore, near the interface between the upper part of the second insulating layer 22a and the p-type base region 2, for example compared with the vicinity of the interface between the lower end of the second insulating layer 22a and the n⁻-type drift region 1, breakdown is more likely to occur. As a result, the withstand voltage of the semiconductor device 100r may decrease.

In the semiconductor device 100 according to the embodiment, as shown in FIG. 3, the upper end of the second conductive portion 22 is positioned lower than the lower end of the p-type base region 2. In other words, the second conductive portion 22 does not face the p-type base region 2 in the X-direction or the Y-direction. Compared with the semiconductor device 100r, the distance between the p-type base region 2 and the second conductive portion 22 is longer. Therefore, the electric field intensity between the p-type base region 2 and the second conductive portion 22 can be reduced, and the occurrence of breakdown between the second insulating layer 22a and the p-type base region 2 can be suppressed. As a result, the withstand voltage of the semiconductor device 100 can be increased.

In the semiconductor device 100, as shown in FIGS. 2 to 4, the gate electrode 10 includes the first electrode part 11 and the second electrode part 12. A portion of the second electrode part 12 is provided on the second part 1b and is connected to the conductive layer 15. Since the gate electrode 10 is electrically connected to the gate pad 43, when the semiconductor device 100 is in the off-state, a large potential difference may occur between the n⁻-type drift region 1 and the gate electrode 10. If the second electrode part 12 is provided on the second part 1b and the p-type base region 2 is not provided on the second part 1b, the second electrode part 12 faces the n⁻-type drift region 1 in the Y-direction. In such a case, the electric field intensity around the second electrode part 12 on the second part 1b increases, and breakdown may occur around the second electrode part 12. As shown in FIG. 2, by having the p-type base region 2 face the second electrode part 12 on the second part 1b, the electric field intensity around the second electrode part 12 can be reduced. As a result, the withstand voltage of the semiconductor device 100 can be further increased.

### First Modification

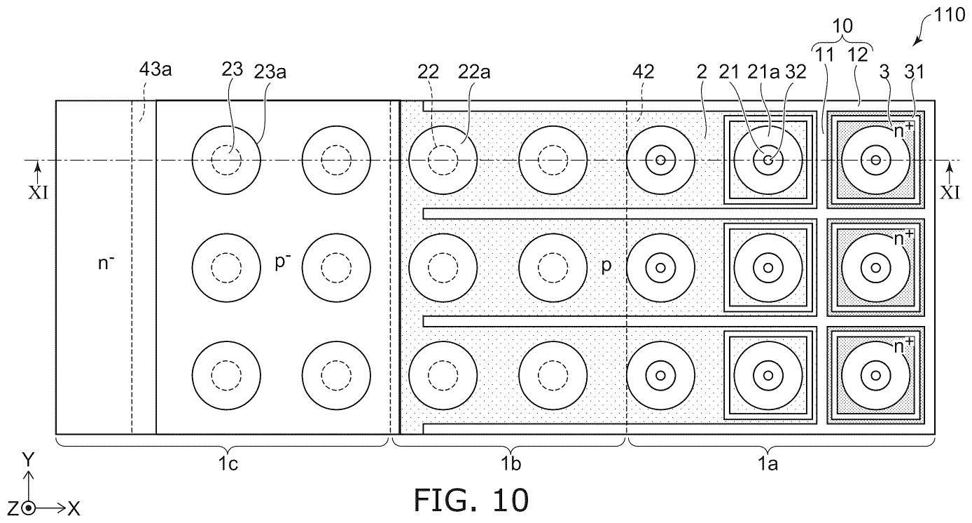

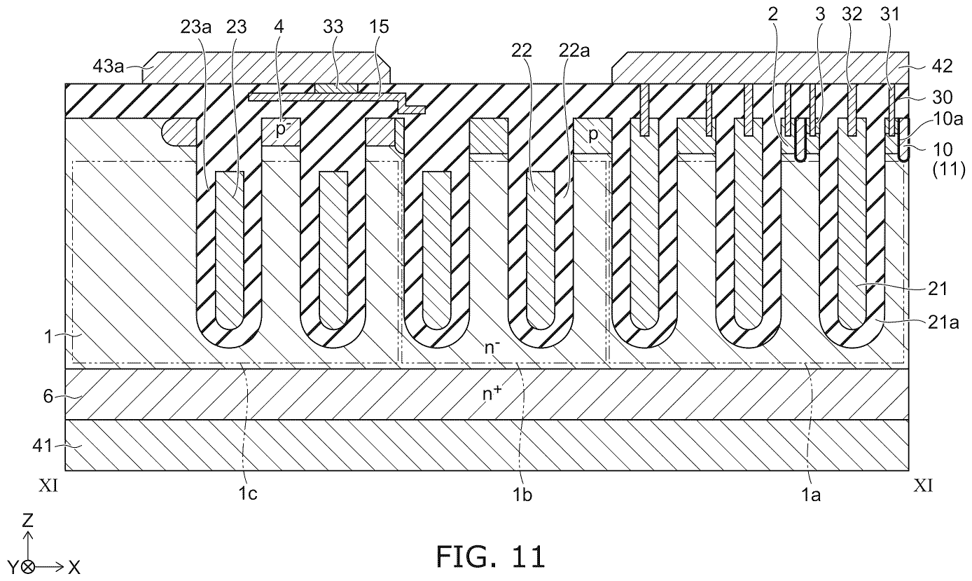

FIG. 10 is a plan view illustrating a part of the semiconductor device according to a first modification. FIG. 11 is the XI-XI cross-sectional view of FIG. 10. Note that in FIG. 10, the conductive layer 15, the insulating layer 30, and the contact plug 33 are omitted, and the source electrode 42 and the gate pad 43 are indicated by dashed lines.

The semiconductor device 110 shown in FIGS. 10 and 11 includes, compared to the semiconductor device 100, a p⁻-type Reduced Surface Field (RESURF) region 4 (a (fourth semiconductor region) and a third conductive portion 23.

The third conductive portion 23 is provided in the third part 1c via a third insulating layer 23a. Multiple third conductive portions 23 are provided in a direction perpendicular to the direction from the first part 1a to the third part 1c. In the illustrated example, multiple third conductive portions 23 are also provided in the direction from the first part 1a to the third part 1c. In the cross-section shown in FIG. 11, the third conductive portion 23 is arranged with the first conductive portion 21 and the second conductive portion 22 in the X-direction.

The p⁻-type RESURF region 4 is provided around the p-type base region 2 along the X-Y plane, and is positioned on the third part 1c. The p-type impurity concentration in the p⁻-type RESURF region 4 is less than the p-type impurity concentration in the p-type base region 2.

The upper end of the third conductive portion 23 is positioned lower than the lower end of the p⁻-type RESURF region 4. The third conductive portion 23 is electrically isolated from the source electrode 42. For example, the electric potential of the third conductive portion 23 is floating.

The third conductive portion 23 includes polysilicon to which impurities have been doped. The third insulating layer 23a includes an insulating material such as silicon oxide, silicon nitride, or silicon oxynitride.

By providing the p⁻-type RESURF region 4, the depletion layer more easily extend toward the outer periphery of the semiconductor device 100 in the third part 1c. As a result, the withstand voltage of the semiconductor device 110 can be increased.

Additionally, the third conductive portion 23 is provided in the third part 1c. In the manufacturing method of the semiconductor device 110, multiple openings are further formed around the multiple openings OP1 and the multiple openings OP2 shown in FIG. 6A in order to form the third conductive portion 23. In such a case, the variation in the shape of the openings OP1 can be further suppressed. In addition, the variation in the shape of the openings OP2 can also be suppressed. The suppression of the variation in the shape of the openings OP2 leads to the suppression of the variation in the shape of the second conductive portion 22 and the variation in the shape of the second insulating layer 22a.

Compared to the third conductive portion 23, the second conductive portion 22 is closer to the cell region of the semiconductor device 100. If the variation in the shapes of the second conductive portion 22 and the second insulating layer 22a is large, the characteristics of the semiconductor device 110 may vary unintentionally. For example, unintended breakdown may occur around the second insulating layer 22a, and the withstand voltage of the semiconductor device 110 may decrease. By providing the third conductive portion 23 and suppressing the variation in the shapes of the second conductive portion 22 and the second insulating layer 22a, the characteristics of the semiconductor device 110 can be further stabilized.

As with e semiconductor device 100, in the semiconductor device 110, the upper end of the second conductive portion 22 is positioned lower than the lower end of the p-type base region 2. Therefore, the occurrence of breakdown between the second insulating layer 22a and the p-type base region 2 can be suppressed, and the withstand voltage of the semiconductor device 110 can be increased.

### Second Modification

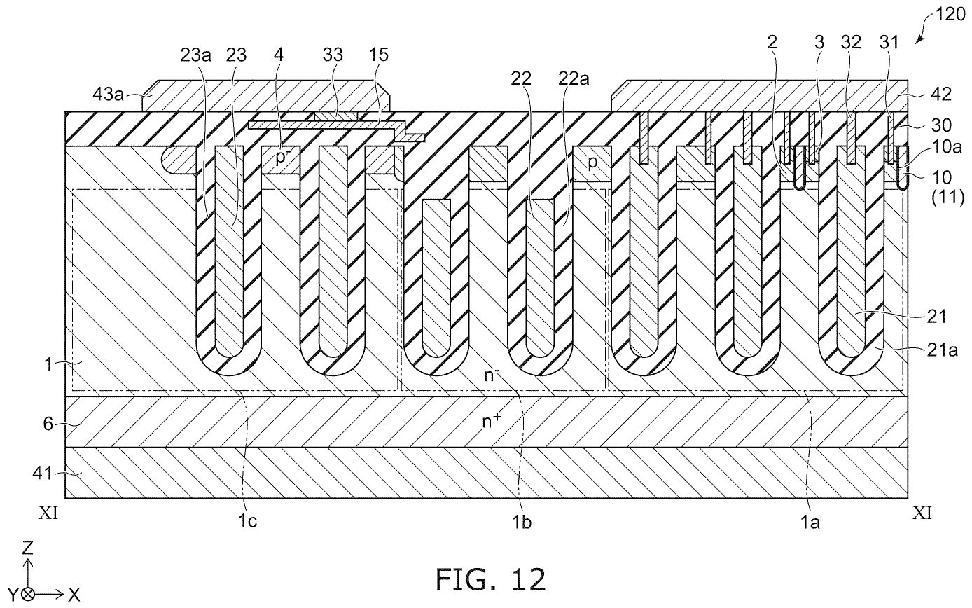

FIG. 12 is a cross-sectional view illustrating a part of the semiconductor device according to a second modification. The semiconductor device 120 shown in FIG. 12 differs from the semiconductor device 110 in the position of the upper end of the third conductive portion 23. In the semiconductor device 120, the upper end of the third conductive portion 23 is positioned higher than the lower end of the p-type base region 2 and the lower end of the p⁻-type RESURF region 4. The upper part of the third conductive portion 23 faces the p⁻-type RESURF region 4 via the third insulating layer 23a in the X-direction or the Y-direction.

The p⁻-type RESURF region 4 is electrically connected to the source electrode 42 via the p-type base region 2 and the contact plug 31. Additionally, the p-type impurity concentration in the p⁻-type RESURF region 4 is less than the p-type impurity concentration in the p-type base region 2. The distance between the third conductive portion 23 and the p-type base region 2 is longer than the distance between the second conductive portion 22 and the p-type base region 2. Therefore, when the semiconductor device 120 is in the off-state, the potential difference generated between the third conductive portion 23 and the p⁻-type RESURF region 4 is smaller than the potential difference generated between the second conductive portion 22 and the p-type base region 2. Therefore, even when the third conductive portion 23 faces the p⁻-type RESURF region 4 in the X-direction or the Y-direction, breakdown is less likely to occur between the third insulating layer 23a and the p⁻-type RESURF region 4.

In the case where the upper end of the second conductive portion 22 is positioned lower than the lower end of the p-type base region 2 and the upper end of the third conductive portion 23 is positioned lower than the lower end of the p⁻-type RESURF region 4 as in the semiconductor device 110, when the process shown in FIG. 7B is carried out, the unevenness of the upper surface of the insulating layer 30 increases directly above the second conductive portion 22 and the third conductive portion 23. As a result, the flatness of the upper surface of the insulating layer 30 tends to decrease. In the case where the upper end of the third conductive portion 23 is positioned higher than the lower end of the p⁻-type RESURF region 4, in the manufacturing process of the semiconductor device 120, the unevenness of the upper surface of the insulating layer 30 directly above the third conductive portion 23 can be reduced. This makes it easier to flatten the upper surface of the insulating layer 30 and improves the manufacturing yield of the semiconductor device 120.

### Third Modification

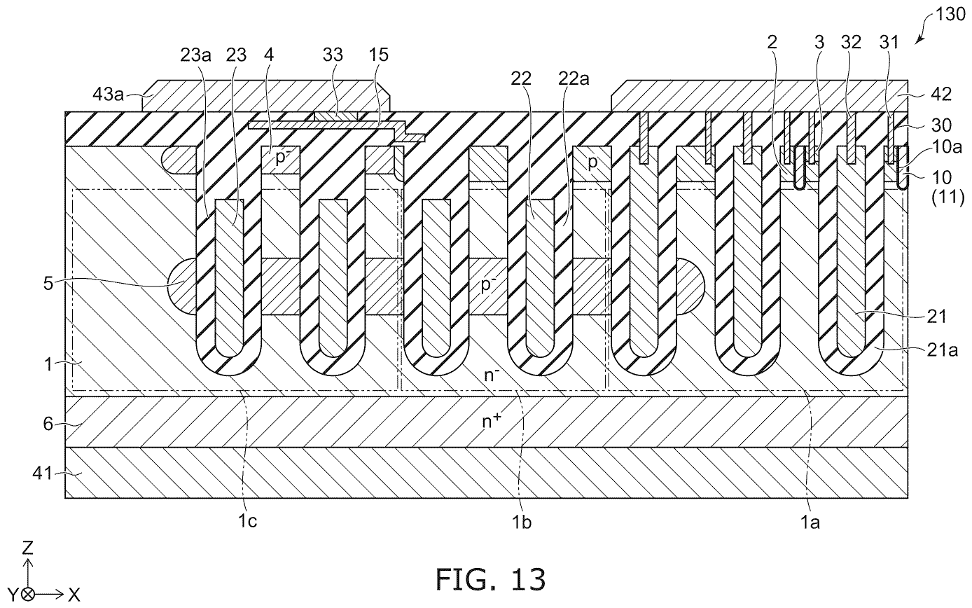

FIG. 13 is a cross-sectional view illustrating a part of a semiconductor device according to a third modification.

The semiconductor device 130 shown in FIG. 13 further includes a p-type semiconductor region 5 (a fifth semiconductor region) compared with the semiconductor device 110. The p⁻-type semiconductor region 5 is provided in the second part 1b and in the third part 1c, and is located around the first part 1a along the X-Y plane. The p⁻-type semiconductor region 5 is separated from the p-type base region 2, the p⁻-type RESURF region 4, and the n⁺-type drain region 6 in the Z-direction.

The p-type impurity concentration in the p⁻-type semiconductor region 5 is less than the p-type impurity concentration in the p-type base region 2. The p-type impurity concentration in the p-type semiconductor region 5 may be the same as the p-type impurity concentration in the p⁻-type RESURF region 4, or it may be different from the p-type impurity concentration in the p⁻-type RESURF region 4.

By providing the p-type semiconductor region 5, the depletion layer tends to extend downward in the second part 1b and the third part 1c. As a result, the withstand voltage of the semiconductor device 130 can be increased.

Additionally, as with the semiconductor device 110, the upper end of the second conductive portion 22 is positioned lower than the lower end of the p-type base region 2 in the semiconductor device 130. Therefore, the occurrence of breakdown between the second insulating layer 22a and the p-type base region 2 can be suppressed, and the withstand voltage of the semiconductor device 130 can be increased.

### Fourth Modification

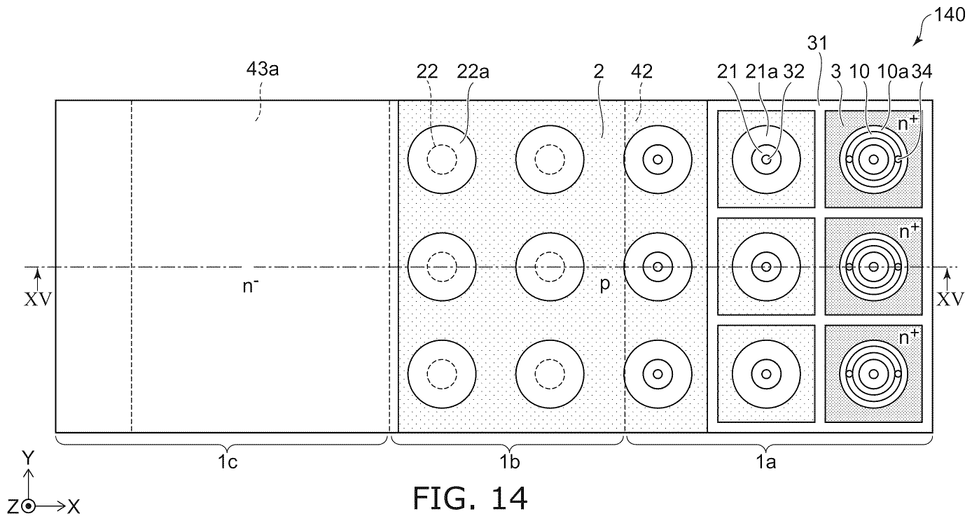

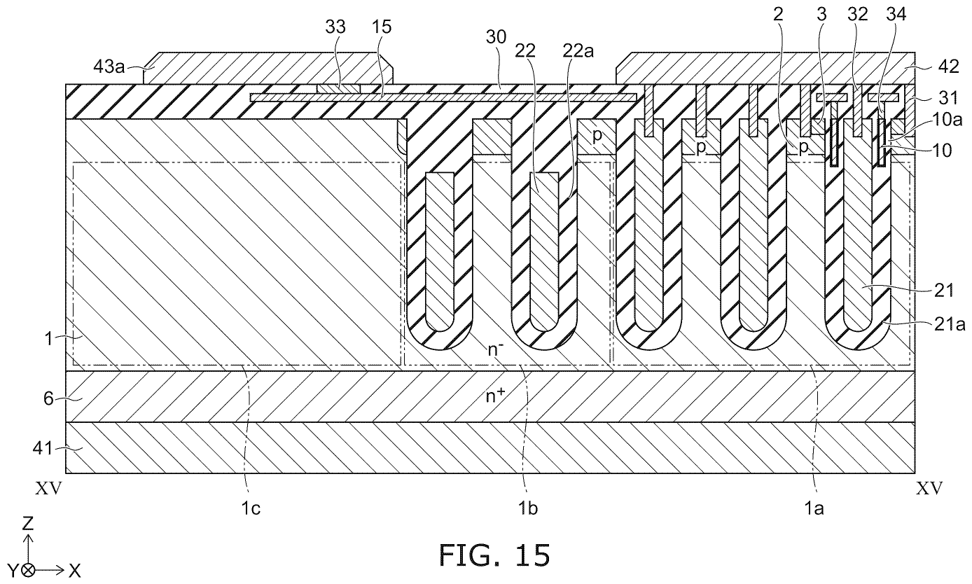

FIG. 14 is a plan view illustrating a part of the semiconductor device according to a fourth modification. FIG. 15 is the XV-XV cross-sectional view of FIG. 14. Note that in FIG. 14, the conductive layer 15, the insulating layer 30, and the contact plug 33 are omitted, and the source electrode 42 and the gate pad 43 are indicated by dashed lines.

In the semiconductor device 140 shown in FIGS. 14 and 15, the structure of the gate electrode 10 differs from that of the semiconductor device 100.

Specifically, the gate electrode 10 is provided in the first insulating layer 21a, and is positioned around the upper part of the first conductive portion 21 along the X-Y plane. The gate electrode 10 and the first conductive portion 21 are electrically isolated. A part of the first insulating layer 21a is positioned between the gate electrode 10 and the p-type base region 2 in the X-direction or the Y-direction, and functions as the gate insulating layer 10a. As shown in FIGS. 14 and 15, the gate electrode 10 may not be provided on the outer periphery of the first part 1a.

As shown in FIG. 15, the conductive layer 15 extends along the X-Y plane in the insulating layer 30 and is provided between the gate electrode 10 and the source electrode 42. A contact plug 34 is provided between the gate electrode 10 and the conductive layer 15, and the gate electrode 10 and the conductive layer 15 are electrically connected. A part of the conductive layer 15 is provided below the gate wiring 43a, and is electrically connected to the gate wiring 43a by the contact plug 33. The gate electrode 10 is electrically connected to the gate pad 43 via the conductive layer 15 and the contact plug 33. The contact plug 31 and the contact plug 32 extend along the Z-direction in the insulating layer 30 without contacting the conductive layer 15.

Additionally, as with the semiconductor device 100, the upper end of the second conductive portion 22 is positioned lower than the lower end of the p-type base region 2 in the semiconductor device 140. Therefore, the occurrence of breakdown between the second insulating layer 22a and the p-type base region 2 can be suppressed, and the withstand voltage of the semiconductor device 140 can be increased.

The various modifications described above may be combined as appropriate. For example, in the semiconductor device 130 according to the third modification, the upper part of the third conductive portion 23 may face the p⁻-type RESURF region 4 in the X-direction or the Y-direction, similar to the second modification. In any of the first to third modifications, the gate electrode 10 structure of the fourth modification may be incorporated.

The embodiment includes the following features.

### Feature 1

A semiconductor device, comprising:
a first electrode;
a first semiconductor region of a first conductivity type provided on the first electrode, the first semiconductor region including a first part and a second part that is provided around the first part along a first plane, the first plane being perpendicular to a first direction from the first electrode toward the first part;
a second semiconductor region of a second conductivity type provided on the first part and the second part;
a third semiconductor region of the first conductivity type provided on the second semiconductor region and positioned on the first part;
a gate electrode facing the second semiconductor region via a gate insulating layer;
a first conductive portion provided in the first part via a first insulating layer, an upper part of the first conductive portion facing the second semiconductor region via the first insulating layer;
a second conductive portion provided in the second part via a second insulating layer, an upper end of the second conductive portion being positioned lower than a lower end of the second semiconductor region; and
a second electrode provided on the second semiconductor region, the third semiconductor region, and the first conductive portion, the second electrode being electrically connected to the second semiconductor region, the third semiconductor region, and the first conductive portion, and being electrically isolated from the second conductive portion.

### Feature 2

The semiconductor device according to feature 1, wherein
the first semiconductor region further includes a third part that is provided around the second part along the first plane,
a fourth semiconductor region of the second conductivity type provided around the second semiconductor region along the first plane, the fourth semiconductor region is positioned on the third part; and
an impurity concentration of the second conductivity type in the fourth semiconductor region is less than an impurity concentration of the second conductivity type in the second semiconductor region.

### Feature 3

The semiconductor device according to feature 2, further comprising a third conductive portion provided in the third part via a third insulating layer,
the third conductive portion being electrically isolated from the second electrode.

### Feature 4

The semiconductor device according to feature 3, wherein
an upper part of the third conductive portion faces the fourth semiconductor region via the third insulating layer.

### Feature 5

The semiconductor device according to feature 3, wherein
an upper end of the third conductive portion is positioned lower than a lower end of the fourth semiconductor region.

### Feature 6

The semiconductor device according to any one of features 2 to 5, further comprising a fifth semiconductor region of the second conductivity type provided in the second part and the third part,
the fifth semiconductor region being positioned lower than the second semiconductor region and the fourth semiconductor region and away from the second semiconductor region and the fourth semiconductor region.

### Feature 7

The semiconductor device according to feature 6, wherein
an impurity concentration of the second conductivity type in the fifth semiconductor region is less than the impurity concentration of the second conductivity type in the second semiconductor region.

### Feature 8

The semiconductor device according to any one of features 1 to 7, wherein
a plurality of the first conductive portions is provided in a second direction and in a third direction,
the second direction is perpendicular to the first direction, and
the third direction is perpendicular to the first direction and intersecting the second direction.

### Feature 9

The semiconductor device according to feature 8, wherein
the gate electrode includes
   a first electrode part extending in the third direction between two of the plurality of first conductive portions adjacent in the second direction, and
   a second electrode part extending in the second direction between two of the plurality of first conductive portions adjacent in the third direction.

### Feature 10

The semiconductor device according to feature 9, wherein
a portion of the second electrode part is provided on the second part and faces the second semiconductor region via the gate insulating layer in the third direction.

### Feature 11

The semiconductor device according to feature 10, wherein
a plurality of the second conductive portion is provided in a direction that is perpendicular to a direction from the first part toward the second part, and
the portion of the second electrode part is positioned between two of the plurality of second conductive portions adjacent to each other.

### Feature 12

The semiconductor device according to feature 8, wherein
the gate electrode is provided in the first insulating layer and is positioned around the upper part of the first conductive portion along the first plane, and
a portion of the first insulating layer between the gate electrode and the second semiconductor region is provided as the gate insulating layer.

### Feature 13

The semiconductor device according to any one of features 1 to 12, wherein
an electric potential of the second conductive portion is floating.

### Feature 14

The semiconductor device according to any one of features 3 to 5, wherein
an electric potential of the third conductive portion is floating.

### Feature 15

The semiconductor device according to any one of features 1 to 14, wherein
the upper end of the second conductive portion is positioned lower than a p-n junction between the first semiconductor region and the second semiconductor region.

### Feature 16

The semiconductor device according to any one of features 1 to 14, further comprising a sixth semiconductor region of the first conductivity type provided between the first electrode and the first semiconductor region,
an impurity concentration of the first conductivity type in the sixth semiconductor region being greater than an impurity concentration of the first conductivity type in the first semiconductor region.

### Feature 17

The semiconductor device according to any one of features 1 to 16, further comprising a third electrode that is separated from the second electrode,
the third electrode being electrically isolated from the second electrode and electrically connected to the gate electrode.

### Feature 18

The semiconductor device according to feature 17, further comprising a fourth semiconductor region of the second conductivity type provided around the third semiconductor region along the first plane,
the first semiconductor region further including a third part that is provided around the second part along the first plane,
the fourth semiconductor region is positioned on the third part, and
a part of the third electrode is positioned on the fourth semiconductor region.

### Feature 19

The semiconductor device according to feature 18, further comprising a conductive layer provided between the fourth semiconductor region and the part of the third electrode,
the gate electrode being electrically connected to the third electrode via the conductive layer.

### Feature 20

The semiconductor device according to feature 19, further comprising:
a third conductive portion provided in the third part via a third insulating layer and electrically isolated from the second electrode; and
a fifth semiconductor region of the second conductivity type provided in the second part and the third part,
the fifth semiconductor region being positioned lower than the second semiconductor region and the fourth semiconductor region and away from the second semiconductor region and the fourth semiconductor region.

As used herein, “or” indicates that at least one of the items listed in the text may be selected.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Moreover, above-mentioned embodiments can be combined mutually and can be carried out.

What is claimed is:

1. A semiconductor device, comprising:
a first electrode;
a first semiconductor region of a first conductivity type provided on the first electrode, the first semiconductor region including a first part and a second part that is provided around the first part along a first plane, the first plane being perpendicular to a first direction from the first electrode toward the first part;
a second semiconductor region of a second conductivity type provided on the first part and the second part;
a third semiconductor region of the first conductivity type provided on the second semiconductor region and positioned on the first part;
a gate electrode facing the second semiconductor region via a gate insulating layer;
a first conductive portion provided in the first part via a first insulating layer, an upper part of the first conductive portion facing the second semiconductor region via the first insulating layer;
a second conductive portion provided in the second part via a second insulating layer, an upper end of the second conductive portion being positioned lower than a lower end of the second semiconductor region; and
a second electrode provided on the second semiconductor region, the third semiconductor region, and the first conductive portion, the second electrode being electrically connected to the second semiconductor region, the third semiconductor region, and the first conductive portion, and being electrically isolated from the second conductive portion.

2. The semiconductor device according to claim 1, wherein
the first semiconductor region further includes a third part that is provided around the second part along the first plane,
a fourth semiconductor region of the second conductivity type provided around the second semiconductor region along the first plane, the fourth semiconductor region is positioned on the third part; and
an impurity concentration of the second conductivity type in the fourth semiconductor region is less than an impurity concentration of the second conductivity type in the second semiconductor region.

3. The semiconductor device according to claim 2, further comprising a third conductive portion provided in the third part via a third insulating layer,
the third conductive portion being electrically isolated from the second electrode.

4. The semiconductor device according to claim 3, wherein
an upper part of the third conductive portion faces the fourth semiconductor region via the third insulating layer.

5. The semiconductor device according to claim 3, wherein
an upper end of the third conductive portion is positioned lower than a lower end of the fourth semiconductor region.

6. The semiconductor device according to claim 2, further comprising a fifth semiconductor region of the second conductivity type provided in the second part and the third part,
the fifth semiconductor region being positioned lower than the second semiconductor region and the fourth semiconductor region and away from the second semiconductor region and the fourth semiconductor region.

7. The semiconductor device according to claim 6, wherein
an impurity concentration of the second conductivity type in the fifth semiconductor region is less than the impurity concentration of the second conductivity type in the second semiconductor region.

8. The semiconductor device according to claim 1, wherein
a plurality of the first conductive portions is provided in a second direction and in a third direction,
the second direction is perpendicular to the first direction, and
the third direction is perpendicular to the first direction and intersecting the second direction.

9. The semiconductor device according to claim 8, wherein
the gate electrode includes
a first electrode part extending in the third direction between two of the plurality of first conductive portions adjacent in the second direction, and
a second electrode part extending in the second direction between two of the plurality of first conductive portions adjacent in the third direction.

10. The semiconductor device according to claim 9, wherein
a portion of the second electrode part is provided on the second part and faces the second semiconductor region via the gate insulating layer in the third direction.

11. The semiconductor device according to claim 10, wherein
a plurality of the second conductive portion is provided in a direction that is perpendicular to a direction from the first part toward the second part, and
the portion of the second electrode part is positioned between two of the plurality of second conductive portions adjacent to each other.

12. The semiconductor device according to claim 8, wherein
the gate electrode is provided in the first insulating layer and is positioned around the upper part of the first conductive portion along the first plane, and
a portion of the first insulating layer between the gate electrode and the second semiconductor region is provided as the gate insulating layer.

13. The semiconductor device according to claim 1, wherein
an electric potential of the second conductive portion is floating.

14. The semiconductor device according to claim 3, wherein
an electric potential of the third conductive portion is floating.

15. The semiconductor device according to claim 1, wherein
the upper end of the second conductive portion is positioned lower than a p-n junction between the first semiconductor region and the second semiconductor region.

16. The semiconductor device according to claim 1, further comprising a sixth semiconductor region of the first conductivity type provided between the first electrode and the first semiconductor region,
an impurity concentration of the first conductivity type in the sixth semiconductor region being greater than an impurity concentration of the first conductivity type in the first semiconductor region.

17. The semiconductor device according to claim 1, further comprising a third electrode that is separated from the second electrode,
the third electrode being electrically isolated from the second electrode and electrically connected to the gate electrode.

18. The semiconductor device according to claim 17, further comprising a fourth semiconductor region of the second conductivity type provided around the third semiconductor region along the first plane,
the first semiconductor region further including a third part that is provided around the second part along the first plane,
the fourth semiconductor region is positioned on the third part, and
a part of the third electrode is positioned on the fourth semiconductor region.

19. The semiconductor device according to claim 18, further comprising a conductive layer provided between the fourth semiconductor region and the part of the third electrode,
the gate electrode being electrically connected to the third electrode via the conductive layer.

20. The semiconductor device according to claim 19, further comprising:
a third conductive portion provided in the third part via a third insulating layer and electrically isolated from the second electrode; and
a fifth semiconductor region of the second conductivity type provided in the second part and the third part,
the fifth semiconductor region being positioned lower than the second semiconductor region and the fourth semiconductor region and away from the second semiconductor region and the fourth semiconductor region.
